(19) United States
(12) Patent Application Publication
(10) Pub. No.: US 2010/0076716 A1
(43) Pub. Date: Mar. 25, 2010

(54) PORTABLE ELECTROMECHANICAL ACTUATOR TEST SYSTEM

(75) Inventors: James Neil Quitmeyer, Chandler, AZ (US); Kevin Eugene Owens, Glendale, AZ (US); Steven Talbert Forrest, Phoenix, AZ (US); Dewey Benson, Chandler, AZ (US)

Correspondence Address: HONEYWELL/IFL;Patent Services, 101 Columbia Road, P.O.Box 2245, Morristown, NJ, 07962-2245, US

(73) Assignee: Honeywell International Inc., Morristown, NJ (US)

(21) Appl. No.: 12/234,299

(22) Filed: Sep. 19, 2008

(51) Int. Cl. G01D 18/00; G01R 31/00

(52) U.S. Cl. 702/121; 324/555

(57) ABSTRACT

A portable electromechanical actuator test system includes a command generator, a rechargeable battery system, an electronic power supply, and a power controller, all disposed within a portable housing. The command generator at least selectively supplies test actuator commands to, and receives operational feedback signals from, an electromechanical actuator (EMA) controller. The rechargeable battery system and electronic power supply each supply electric power. The power controller is coupled to receive the electric power supplied from both the rechargeable battery system and the electronic power supply, and is operable to at least selectively supply electric power to the EMA controller and to an EMA that is controlled by the EMA controller.

### TECHNICAL FIELD

The present invention generally relates to electromechanical actuator (EMA) testing and, more particularly, to portable system that allows one or more EMAs to be tested at various remote platforms.

### BACKGROUND

Actuators are used in myriad devices and systems. For example, many vehicles including, for example, aircraft, spacecraft, watercraft, and numerous other terrestrial and non-terrestrial vehicles, include one or more actuators to effect the movement of various control surfaces or components. More recently, as systems are being designed to rely more on electrical power and less on pneumatic or hydraulic fluid power, electromechanical actuators (EMAs) are more often being used. An EMA typically includes an electric motor that, when properly energized, will supply a torque to a suitable actuation device, which in turn positions a component.

The systems that include EMAs are being designed to exhibit relatively high frequency responses and increased slew rates. Moreover, in some applications such as, for example, aircraft flight surface control systems and missile thrust vector control systems, the EMAs that are used may be subject to relatively severe environmental conditions, as well as relatively high magnitude shock and vibration. It would thus be desirable to test EMAs, both prior to and after placement into service, to ensure the EMAs have the initial and continued ability to meet relatively high system frequency response and increased system slew rates, and/or to meet the environmental conditions to which they will be exposed. Unfortunately, many facilities do not include systems to allow one or more EMAs to be adequately tested, in either pre- or post-installation environments, with a sufficient level of rigor. Moreover, presently available test systems are either not sufficiently portable or do not provide an adequate level of EMA testing to justify transporting the test system to a remote facility for pre- or post-installation testing.

Hence there is a need for a portable EMA test system that allows one or more pre- or post-installation EMAs to be adequately tested. The present invention addresses one or more of these needs.

### BRIEF SUMMARY

In one embodiment, and by way of example only, a portable electromechanical actuator test system includes a portable housing, a command generator, a rechargeable battery system, an electronic power supply, and a power controller. The command generator is disposed within the portable housing and is operable to at least selectively supply test actuator commands to, and receive operational feedback signals from, an electromechanical actuator (EMA) controller. The rechargeable battery system is disposed within the portable housing and is operable to supply electric power. The electronic power supply is disposed within the portable housing and is operable to supply electric power. The power controller is disposed within the portable housing and is coupled to receive the electric power supplied from both the rechargeable battery system and the electronic power supply. The power controller is operable to at least selectively supply electric power to the EMA controller and to an EMA that is controlled by the EMA controller.

In another exemplary embodiment, a portable electromechanical actuator test system includes a portable housing, a command generator, a rechargeable battery system, an electronic power supply, and a power controller. The command generator is disposed within the portable housing and is adapted to receive input commands from a remote facility control. The command generator is responsive to the input commands to at least selectively supply test actuator commands to, and receive operational feedback signals from, an electromechanical actuator (EMA) controller, and to at least selectively transmit feedback data to the remote facility. The rechargeable battery system is disposed within the portable housing and is operable to supply electric power. The electronic power supply is disposed within the portable housing and is operable to supply electric power. The power controller is disposed within the portable housing and is coupled to receive the electric power supplied from both the rechargeable battery system and the electronic power supply. The power controller is operable to at least selectively supply electric power to the EMA controller and to an EMA that is controlled by the EMA controller.

Other desirable features and characteristics of the portable EMA test system will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and wherein:

FIG. 1 depicts an exemplary embodiment of a portable electromechanical actuator test system connected to a remote platform for testing one or more electromechanical actuators in the remote platform, and how it is connectable to various other remote platforms; and

FIG. 2 depicts a functional block diagram of an exemplary embodiment of the portable electromechanical actuator test system of FIG. 1.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

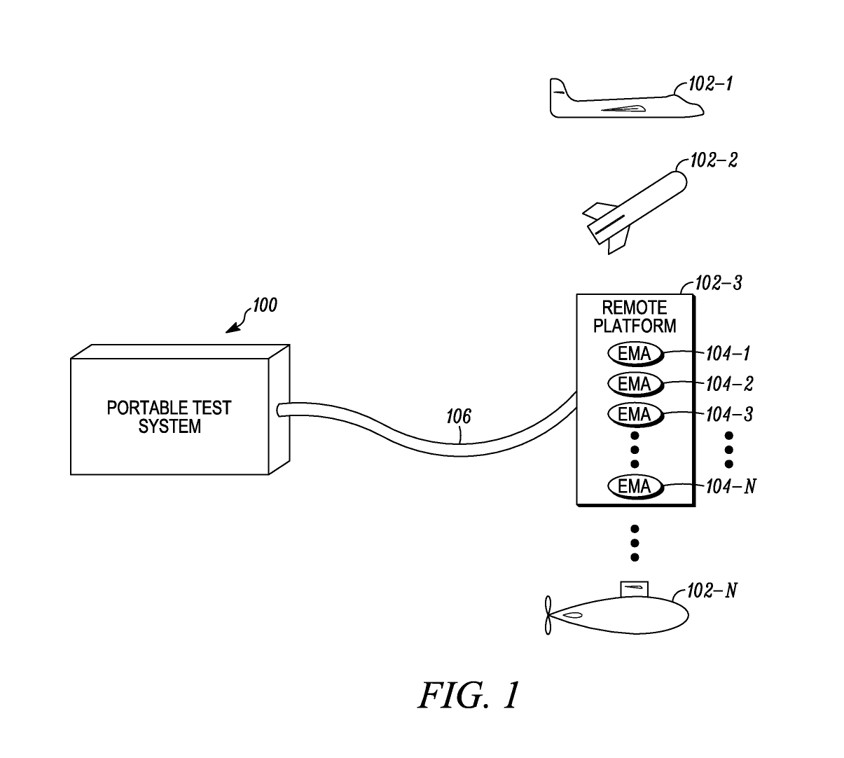

Referring first to FIG. 1, an exemplary embodiment of a portable electromechanical actuator (EMA) test system 100 is depicted. The portable EMA test system 100, as the nomenclature used herein connotes, is readily transportable to various remote facilities 102 (e.g., 102-1, 102-2, 102-3, . . . 102-N), where it may be used to test one or more EMAs 104 (e.g., 104-1, 104-2, 104-3, . . . 104-N) at the remote facility 102. When transported to a remote facility 102, the portable EMA test system 100 is connected to the one or more EMAs 104 at the remote facility via, for example, one or more interconnecting test cables 106. It will be appreciated that the remote facilities may be, for example, customer or vendor test facilities, or end-use environments in which the one or more EMAs 104 are installed for used. Some examples of end-use environments include, but are not limited to, aircraft, surface ships, submarines, satellites, rockets, missiles, and manufacturing facilities. Advantageously, the portable EMA test system 100 allows the one or more EMAs 104 at the remote facility 102 to be tested without having to remove the EMAs 104 from the remote facility 102.

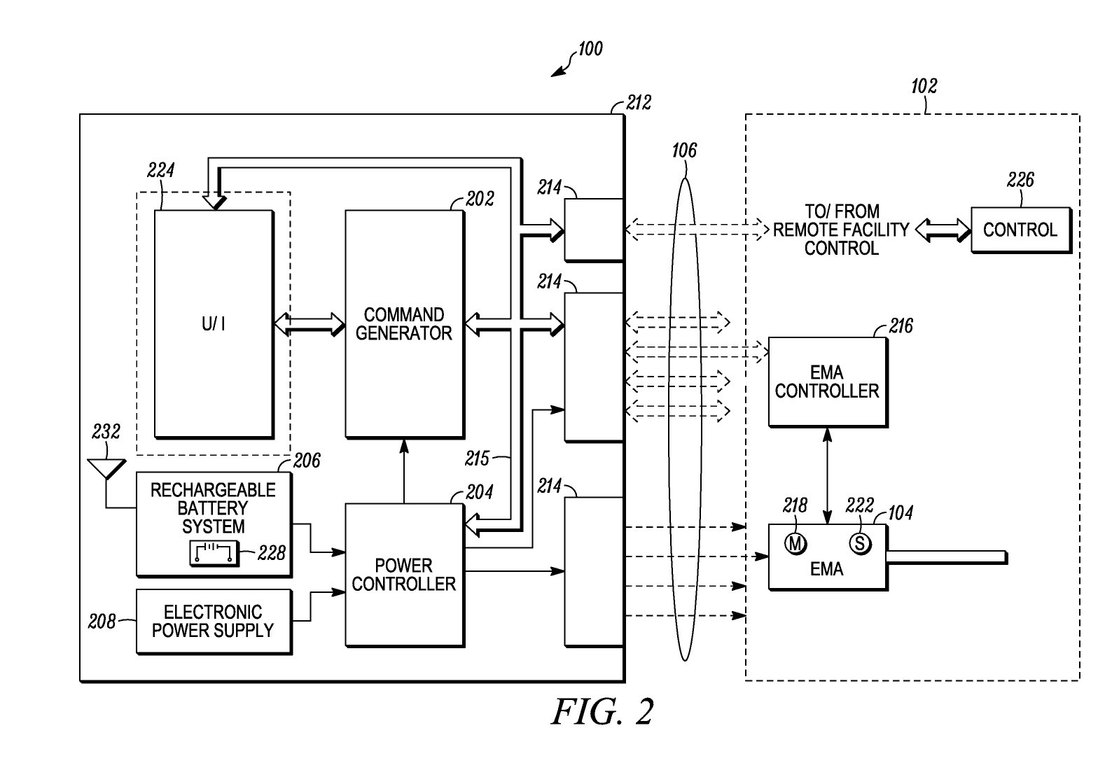

The portable EMA test system 100 may be variously configured and implemented. Preferably, as was noted above, it is readily transportable to and from various remote facilities 102. It will be appreciated that the portable EMA test system 100 may be configured to be transported by hand, or it may be configured to be readily transported by a vehicle. It will additionally be appreciated that the portable EMA test system 100 may be configured with one or more wheels 108 and/or one or more handles 112, as the case may be, to facilitate its transportation to and from a remote facility 102, and to facilitate its movement within and around the remote facility 102. A functional block diagram of an exemplary embodiment of the portable EMA test system 100 is depicted in FIG. 2, and with reference thereto, will now be described.

The portable EMA test system 100 includes a command generator 202, a power controller 204, a rechargeable battery system 206, and an electronic power supply 208, all disposed within a portable housing 212. As FIG. 2 depicts, and as was described above, the portable EMA test system 100 may be transported to a remote facility 102 and connected, via one or more input/output (I/O) connectors 214, to one or more EMAs 104 at the remote facility 102 via one or more suitable interconnecting test cables 106. In FIG. 2 the portable EMA test system 100 is shown connected to a single EMA 104. However, as was also described above, the portable EMA test system 100 may be configured to allow it to be simultaneously connected to a plurality of EMAs 104.

Before proceeding further, it is noted that the EMA 104 being tested is coupled, at the remote facility 102, to an EMA controller 216. The EMA 104 may be variously configured and may include, among various other components, a motor 218 and one or more sensors 222. The EMA controller 216 is responsive to actuator commands it receives, and from feedback signals supplied thereto from the one or more sensors 222, to controllably energize the motor 218 from a power source. The EMA 104, in response to its motor 218 being energized, generates a drive force or drive torque that may be used to move one or more devices or components.

Returning now to the description of the portable EMA test system 100, the command generator 202 is in operable communication with a suitable communication bus 215, and is operable to at least selectively supply test actuator commands to, and receive operational feedback signals from, one or more EMA controllers 216. More specifically, the command generator 202 is adapted to receive input commands and is responsive to these input commands to at least selectively supply test actuator commands, via the communication bus 215, appropriate I/O connector 214, and test cable(s) 106, to one or more EMA controllers 216. In the depicted embodiment the portable EMA test system 100 is connected to a single EMA controller 216 and a single EMA 104. Thus, the EMA controller 216, in response to the test actuator commands it receives, selectively energizes the EMA 104 to move to a commanded position. It is noted that the command generator 202 is preferably configured to supply either analog or digital test actuator commands to the EMA controller 216 depending, for example, on the configuration of the EMA controller 216. In this regard, the communication bus 215, the I/O connectors 214, and the associated test cable(s) 106, may accommodate numerous and varied digital and/or analog communication protocols.

The input commands supplied to the command generator 202 may originate from a user interface 224, from a remote facility control 226, or from both if needed or desired. In this manner, the portable EMA test system 100 may be controlled and monitored via the user interface 224, or via the remote facility control 226. In any case, the input commands supplied to the command generator 202 are preferably identical to, or at least simulate, the commands that are supplied from a system controller that is installed in the same end-use system in which the EMA 104 is installed. For example, the input commands may be identical to, or at least simulate, commands supplied from a flight computer if the EMA 104 is installed in a flight control system or an attitude control system. It will be appreciated that if the remote facility 102 includes the end-use system, then the remote facility control 226 may be the system controller (e.g., the flight computer, etc.).

The command generator 202, in addition to supplying actuator commands and receiving feedback signals, at least selectively transmits feedback data to the user interface 224, the remote facility control 226, or both (if needed or desired). These feedback data may vary in type, but are preferably representative of suitable operational characteristics of the EMA(s) 104 and EMA controller(s) 216 under test. It may thus be appreciated that the feedback signals received from the EMA controller(s) 216 include various fault-related signals and various telemetry signals. The command generator may be configured to transmit the feedback data to the user interface 224 and/or remote facility control 226 either automatically, in real-time or at a set periodicity, or in response to a query from the user interface 224 and/or remote facility control 226. The commands and feedback data may also be saved for later use such as, for example, to be plotted and analyzed.

It is noted that in FIG. 2 the user interface 224 is outlined by a dashed line. This is done to illustrate that the user interface 224 may be an integral part of the system 100, and thus mounted on or within the portable housing 212, or it may be a separate device. In both instantiations, it will be appreciated that the user interface 224 may be variously implemented and configured. For example, the user interface 224 may be implemented as an application specific device or as any one of numerous general-purpose computing devices including, for example, various notebook computers, or hand-held computers. It will additionally be appreciated that the user interface 224, if it is implemented apart from the portable housing 212, may be placed in operable communication with the command generator 202 and/or remote facility control 226 via a wired or wireless medium.

The power controller 204 is coupled to receive electrical power supplied from the rechargeable battery system 206 and the electronic power supply 208. The power controller 204 is additionally coupled, via appropriate I/O connectors 214 and one or more cables 106, to the EMA 104 and its associated EMA controller 216. The power controller 204 is operable to at least selectively supply electric power to the EMA 104 and its associated EMA controller 216. In this regard, it will be appreciated that the electric power supplied from the power controller 204 to the EMA controller 216 is relatively low-level electric power (e.g., ±28 VDC, ±12 VDC, etc.) suitable for energizing and operating the EMA controller 216. Conversely, the electric power supplied from the power controller 204 to the EMA 104 is relatively high-level electric power (e.g., 120 VAC, 220 VAC, 300 VDC, etc.) suitable for energizing and operating the EMA motor 218.

As FIG. 2 additionally depicts, the power controller 204 is connected to the communication bus 215. The power controller 204 may thus receive input commands via the communication bus 215, which may be supplied by the command generator 202, the user interface 224, and or the remote facility control 226. The input commands, no matter the origin, preferably command the power controller 204 to supply only the relatively low-level power electric power or to supply both the relatively low-level and the relatively high-level electric power. Preferably, the power controller 204 is initially commanded to supply only the relatively low-level electric power. Then, after a suitable period of time, it is commanded to supply both the relatively low-level and relatively high-level electric power. This allows the EMA 104 and EMA controller 216 to warm-up. However, because the power controller 204 is not yet supplying the relatively high-level electric power, the EMA 104 will be unable to move, in the unlikely event a fault exists that would cause an unintended movement of the EMA 104. It will be appreciated that the power controller 204 may, in some embodiments, be configured to implement this functionality automatically, and not in response to input commands from another device.

As noted above, the power controller 204 receives electrical power from the rechargeable battery system 206 and the electronic power supply 208. The rechargeable battery system 206, as may be appreciated, includes one or more rechargeable batteries 228, and an input 232 that is adapted to receive electrical power from a non-illustrated electric power source. The rechargeable batteries 228 may be any one of numerous types of suitable batteries that are capable of supplying relatively high-level electric power to the power controller 204, for subsequent supply to the EMA 104. A non-limiting example of suitable batteries 228 is thermal batteries.

The electronic power supply 208 is configured to supply relatively low-level electric power to the power controller 204, for subsequent supply to the EMA controller 216. The electronic power supply 208 may be implemented as any one of numerous types of electronic power supplies now known or developed in the future. The electronic power supply 208 may be configured to be energized from the rechargeable battery system 206 or from a non-illustrated electrical power source.

The portable EMA test system 100 described herein may be readily transported to various remote facilities to test one or more EMAs 104 at the remote facilities. The system 100 may be used to test one or more pre- or post-installation EMAs, depending upon whether the EMAs are located at a remote design, test, and/or repair facility, or are disposed within an end-use environment.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A portable electromechanical actuator test system, comprising:
a portable housing;
a command generator disposed within the portable housing and operable to at least selectively supply test actuator commands to, and receive operational feedback signals from, an electromechanical actuator (EMA) controller;
a rechargeable battery system disposed within the portable housing and operable to supply electric power;
an electronic power supply disposed within the portable housing and operable to supply electric power; and
a power controller disposed within the portable housing and coupled to receive the electric power supplied from both the rechargeable battery system and the electronic power supply, the power controller operable to at least selectively supply electric power to the EMA controller and to an EMA that is controlled by the EMA controller.

2. The system of claim 1, wherein the command generator is adapted to receive input commands and is operable, in response thereto, to at least selectively supply the test actuator commands.

3. The system of claim 1, wherein the command generator is adapted to receive the input commands from a remote facility control.

4. The system of claim 3, wherein the command generator is further operable to at least selectively transmit feedback data to the remote facility control.

5. The system of claim 2, further comprising:
a user interface in operable communication with the command generator and operable to at least selectively supply the input commands to the command generator.

6. The system of claim 5, wherein command generator is further operable to at least selectively transmit feedback data to the user interface.

7. The system of claim 5, wherein the user interface is wirelessly in operable communication with the command generator.

8. The system of claim 5, wherein the user interface is adapted to be at least selectively coupled to the EMA controller.

9. The system of claim 1 wherein:
the command generator is further operable to at least selectively supply test actuator commands to, and receive operational feedback signals from, a plurality of EMA controllers; and
the power controller is further operable to at least selectively supply electric power to the plurality of EMA controllers and to each of the EMAs that are controlled by the plurality of EMA controllers.

10. The system of claim 1, wherein the command generator is configured to selectively supply digital actuator commands and analog actuator commands.

11. A portable electromechanical actuator test system, comprising:
a portable housing;
a command generator disposed within the portable housing and adapted to receive input commands from a remote facility control, the command generator responsive to the input commands to at least selectively supply test actuator commands to, and receive operational feedback signals from, an electromechanical actuator (EMA) controller, and to at least selectively transmit feedback data to the remote facility;
a rechargeable battery system disposed within the portable housing and operable to supply electric power;
an electronic power supply disposed within the portable housing and operable to supply electric power;
a power controller disposed within the portable housing and coupled to receive the electric power supplied from both the rechargeable battery system and the electronic power supply, the power controller operable to at least selectively supply electric power to the EMA controller and to an EMA that is controlled by the EMA controller.

12. The system of claim 2, further comprising:
a user interface in operable communication with the command generator and operable to at least selectively supply user interface input commands to the command generator.

13. The system of claim 12, wherein command generator is further operable to at least selectively transmit feedback data to the user interface.

14. The system of claim 12, wherein the user interface is wirelessly in operable communication with the command generator.

15. The system of claim 12, wherein the user interface is adapted to be at least selectively coupled to the EMA controller.

16. The system of claim 11, wherein the command generator is configured to selectively supply digital actuator commands and analog actuator commands.

17. The system of claim 11 wherein:
the command generator is further operable to at least selectively supply test actuator commands to, and receive operational feedback signals from, a plurality of EMA controllers; and
the power controller is further operable to at least selectively supply electric power to the plurality of EMA controllers and to each of the EMAs that are controlled by the plurality of EMA controllers.
